(19) United States
(12) Patent Application Publication
(10) Pub. No.: US 2022/0376035 A1
(43) Pub. Date: Nov. 24, 2022

(54) INTEGRATED CIRCUITS WITH EMBEDDED LAYERS

(71) Applicant: Cirrus Logic International Semiconductor Ltd., Edinburgh (GB)

(72) Inventors: David PATTEN, Austin, TX (US); Aleksey S. KHENKIN, Lago Vista, TX (US)

(73) Assignee: Cirrus Logic International Semiconductor Ltd., Edinburgh (GB)

(21) Appl. No.: 17/741,687

(22) Filed: May 11, 2022

Related U.S. Application Data
(60) Provisional application No. 63/190,453, filed on May 19, 2021.
(60) Provisional application No. 63/257,206, filed on Oct. 19, 2021.

(30) Foreign Application Priority Data
Nov. 25, 2021 (GB) 2116974.3

(51) Int. Cl. H01L 49/02

(52) U.S. Cl. CPC H01L 28/10

(57) ABSTRACT

The disclosure relates to integrated circuits and methods of manufacture. A method involves forming a first set of one or more circuit layers on a semiconductor substrate, placing at least one prefabricated layer portion onto the first set of circuit layers to form a component, and forming a second set of one or more circuit layers over the first set of circuit layers and the at least prefabricated layer portion. The prefabricated layer portion may be a magnetic layer portion placed to form a magnetic component such as a magnetic core of an inductor or transformer. The method may also comprise forming the prefabricated layer portion.

The present disclosure claims priority to U.S. Provisional Patent Application Ser. No. 63/190,453, filed May 19, 2021, U.S. Provisional Patent Application Ser. No. 63/257,206, filed Oct. 19, 2021, and United Kingdom Patent Application No. 2116974.3, filed Nov. 21, 2021, each of which is incorporated by reference herein in its entirety.

The field of representative embodiments of this disclosure relates to methods, apparatus and/or implementations concerning or relating to integrated circuits with embedded layers, and in particular to integrated circuits with embedded magnetic layers, such as magnetic cores.

There are a number of applications where it may be desirable for integrated circuits (ICs) to be implemented so as to operate with reactive components, such as inductors and/or transformers comprising a magnetic core for example. In some applications, a circuit component such as an inductor comprising a magnetic core may be implemented as a separate, external component to the IC, i.e. as an off-chip component, and connected to the IC via suitable contacts. In at least some applications, however, it may be beneficial, e.g. for size and cost reasons, for the circuit component to be formed as part of the IC itself.

Circuit components comprising magnetic materials have been formed as part of an IC by deposition and patterning the component materials. For example, an integrated inductor may be formed by depositing and patterning a metallic material to form lower windings, with a magnetic core material being deposited and patterned on a dielectric over the lower windings. Another metallic layer may then be deposited on a dielectric over the core material and patterned to form upper windings, with suitable connections through the dielectric to the lower windings.

Such a process can thus usefully produce integrated circuit components comprising magnetic material, such as inductors or transformers, for example, as part of an IC die.

However, such a deposition process for the magnetic core material may involve some limitations in the machinery, tooling, process temperature(s) and materials that may be used for the deposited magnetic core material and/or the magnetic structures that may be formed.

Embodiments of the present disclosure relate to integrated circuits including reactive, e.g. magnetic, components, and methods and apparatus for manufacture thereof that may avoid at least some such limitations.

According to an aspect of the disclosure there is provided an integrated circuit comprising: a first set of one or more circuit layers on a semiconductor substrate; at least one fabricated magnetic layer portion forming a magnetic component on the first set of circuit layers, wherein the at least one fabricated magnetic layer portion comprises a magnetic layer coupled to the first set of one or more circuit layers by an adhesion layer; and a second set of one or more circuit layers on top of the first set of circuit layers and the at least fabricated magnetic layer portion.

In some examples, the at least one fabricated magnetic layer portion may have an edge formed by cutting. The at least one fabricated magnetic layer portion may have an edge sidewall which is substantially perpendicular to a plane of the magnetic layer portion.

The at least one fabricated magnetic layer portion may be magnetically anisotropic with a magnetic hard axis. The at least one prefabricated magnetic layer portion may comprise a plurality of magnetic layer portions. At least some of the plurality of magnetic layer portions may be oriented so that the magnetic hard axis is oriented in different directions at different positions of the magnetic component.

The magnetic component may comprise a plurality of fabricated magnetic layer portions stacked on top of one another.

The thickness of the magnetic component formed by the at least one prefabricated magnetic layer portion may be at least 10 μm.

The at least one prefabricated magnetic layer portions may form a magnetic component with a toroidal shape. A plurality of magnetic layer portions may form the toroidal shape.

The magnetic component may be a magnetic core of an inductor or a transformer. The first set of circuit layers may comprise a first conductive layer patterned to form a set of lower windings for the inductor or transformer and the second set of circuit layers may comprise a second conductive layer patterned to form a set of upper windings for the inductor.

The adhesion layer may a cured adhesion layer.

In another aspect there is provided a method of fabricating an integrated circuit comprising: forming a first set of one or more circuit layers on a semiconductor substrate; placing at least one prefabricated magnetic layer portion onto the first set of circuit layers to form a magnetic component; and forming a second set of one or more circuit layers over the first set of circuit layers and the at least prefabricated magnetic layer portion.

In some examples, the least one prefabricated magnetic layer portion may comprise a layer of magnetic material and an attachment layer.

Placing the at least one prefabricated magnetic layer portion onto the first set of circuit layers may comprise positioning the at least one prefabricated magnetic layer portion onto the first set of circuit layers. The method may also comprise curing an adhesive of the attachment layer after positioning the at least one prefabricated magnetic layer portion onto the first set of circuit layers.

The at least one prefabricated magnetic layer portion may have an edge formed by cutting. The at least one prefabricated magnetic layer portion may have an edge sidewall which is substantially perpendicular to a plane of the magnetic layer portion.

In some examples, the at least one prefabricated magnetic layer portion may be magnetically anisotropic with a magnetic hard axis. Placing the at least one prefabricated magnetic layer portion onto the first set of circuit layers to form a magnetic component may comprise placing a plurality of magnetic layer portions onto the first set of circuit layers. At least some of the plurality of magnetic layer portions may be oriented so that the magnetic hard axis is oriented in different directions at different positions of the magnetic component.

Placing the at least one prefabricated magnetic layer portion onto the first set of circuit layers to form a magnetic component may comprise stacking a plurality of prefabricated magnetic layer portions on top of one another.

In some examples the thickness of the magnetic component formed by the at least one prefabricated magnetic layer portion may be at least 10 μm.

The at least one prefabricated magnetic layer portion may be placed onto the first set of circuit layers to form a magnetic component with a toroidal shape. Placing the at least one prefabricated magnetic layer portion onto the first set of circuit layers to form a magnetic component may comprise placing a plurality of prefabricated magnetic layer portions onto the first set of circuit layers to form the toroidal shape.

The magnetic component may be a magnetic core of an inductor or a transformer. The first set of circuit layers may comprise a first conductive layer patterned to form a set of lower windings for the inductor or transformer and the second set of circuit layers may comprise a second conductive layer patterned to form a set of upper windings for the inductor and to provide electrical connections to the set of lower windings.

The at least one prefabricated magnetic layer portion may be cut from a panel comprising a layer of magnetic material on an attachment layer on a base. The base may comprise a dicing tape. The prefabricated magnetic layer may be formed on a carrier and transferred to the attachment layer on the base to form the panel.

Embodiments also relate to an integrated circuit produced according to the method of any of the variants described herein.

In an additional aspect there is provided an integrated circuit comprising an integrated inductor or transformer having a magnetic core wherein a sidewall of the magnetic core is substantially perpendicular to a plane of the magnetic core.

In an additional aspect there is provided an integrated circuit comprising an integrated inductor or transformer having an integral magnetic core formed of magnetic material, wherein the magnetic material is magnetically anisotropic with a magnetic hard axis and wherein the magnetic hard axis is oriented in different directions at different positions of the magnetic core.

In an additional aspect there is provided an integrated circuit comprising an integrated inductor or transformer having a magnetic core, wherein the magnetic core has a toroidal shape formed from a plurality of portions of magnetic material.

In an additional aspect there is provided an integrated circuit comprising an integrated inductor or transformer having a magnetic core, wherein the magnetic core has a thickness of at least 10 μm.

In an additional aspect there is provided an integrated circuit comprising an integrated inductor or transformer having a magnetic core, wherein the magnetic core is formed from a stack of magnetic portions, each magnetic portion comprising a layer of magnetic material on an adhesion layer.

In each of these additional aspects, a sidewall of the magnetic core may be a sidewall formed by cutting and/or the magnetic core may have an edge sidewall which is substantially perpendicular to a plane of the magnetic core. The magnetic core may be located between a first set of circuit layers and a second set of circuit layers and coupled to the first set of circuit layers by an adhesive layer. The adhesion layer comprises a cured adhesion layer. The first set of circuit layers may comprise a first conductive layer patterned to form a set of lower windings for the inductor or transformer and the second set of circuit layers may comprise a second conductive layer patterned to form a set of upper windings for the inductor. The magnetic core may be formed from one or more magnetic layer portions which are magnetically anisotropic with a magnetic hard axis. The magnetic core may comprise a plurality of magnetic layer portions, wherein at least some of the plurality of magnetic layer portions are oriented so that the magnetic hard axis is oriented in different directions at different positions of the magnetic component. The magnetic core may comprise a plurality of fabricated magnetic layer portions stacked on top of one another. The thickness of the magnetic core may be at least 10 μm. The magnetic core may have a toroidal shape.

In a further aspect there is provided a method of fabricating an integrated circuit comprising: forming a first set of one or more circuit layers on a semiconductor substrate; placing at least one prefabricated material layer portion onto the first set of circuit layers to form a first component of the integrated circuit; and forming a second set of one or more circuit layers over the first set of circuit layers and the at least prefabricated material layer portion.

In a yet further aspect there is provided an integrated circuit comprising: a first set of one or more circuit layers on a semiconductor substrate; at least one fabricated capacitor layer portion positioned over the first set of circuit layers to form a capacitive component.

The at least one fabricated capacitor layer portion may have an edge formed by cutting. The at least one fabricated capacitor layer portion may have an edge sidewall which is substantially perpendicular to a plane of the capacitor layer portion. The adhesion layer may be a cured adhesion layer.

In a yet further aspect there is provided an integrated circuit comprising: a first set of one or more circuit layers on a semiconductor substrate; at least one prefabricated reactive component layer portion positioned over the first set of circuit layers to form a reactive component.

In a yet further aspect there is provided an integrated circuit comprising: a first set of one or more circuit layers on a semiconductor substrate; at least one prefabricated reactive component layer portion positioned over the first set of circuit layers; and a second set of one or more circuit layers positioned over the first set of circuit layers and the at least prefabricated reactive component layer portion to form a reactive component.

It should be noted that, unless expressly indicated to the contrary herein or otherwise clearly incompatible, then any feature described herein may be implemented in combination with any one or more other described features.

For a better understanding of examples of the present disclosure, and to show more clearly how the examples may be carried into effect, reference will now be made, by way of example only, to the following drawings in which:

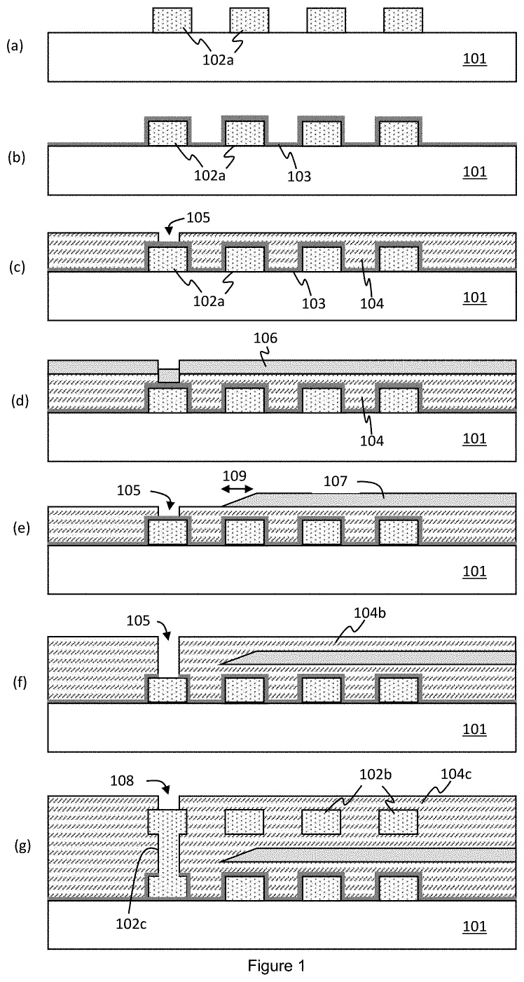

FIG. 1 illustrates a process for fabricating an IC that includes depositing and forming a magnetic layer;

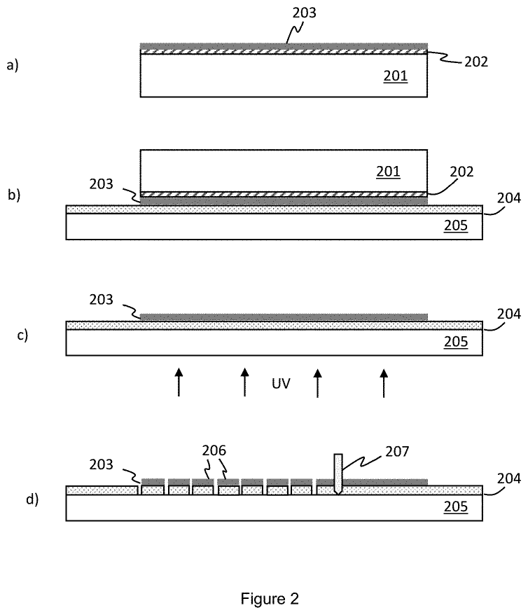

FIG. 2 illustrates a process for prefabricating a magnetic layer;

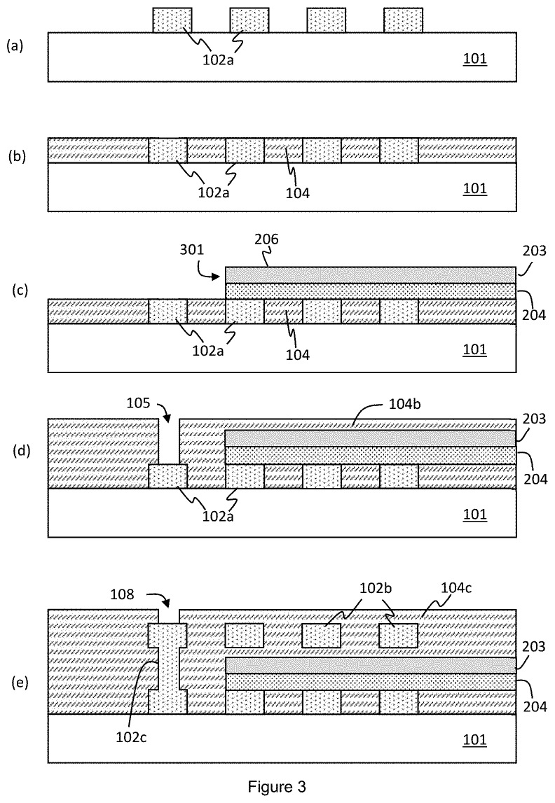

FIG. 3 illustrates a process for fabricating an IC that embeds a prefabricated magnetic layer;

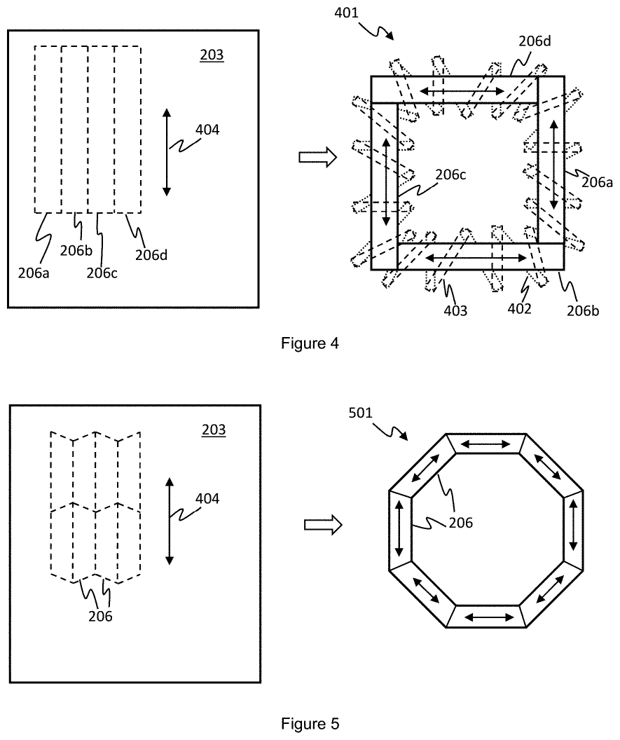

FIG. 4 illustrates one example of forming a magnetic core from a plurality of magnetic layer portions;

FIG. 5 illustrates another example of forming a magnetic core from a plurality of magnetic layer portions; and

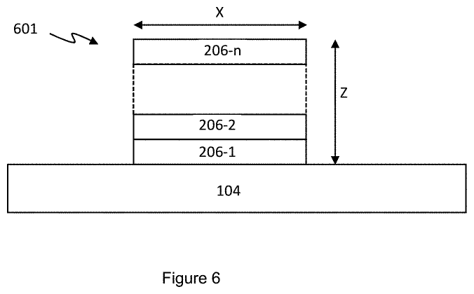

FIG. 6 illustrates one example of forming a magnetic core from a stack of plurality of magnetic layer portions.

The description below sets forth example embodiments according to this disclosure. Further example embodiments and implementations will be apparent to those having ordinary skill in the art. Further, those having ordinary skill in the art will recognize that various equivalent techniques may be applied in lieu of, or in conjunction with, the embodiments discussed below, and all such equivalents should be deemed as being encompassed by the present disclosure.

As noted above, it has been proposed to form integrated circuits (ICs) with integrated circuit components comprising magnetic material, for instance such as an integrated inductor with a magnetic core, through a deposition and patterning processes.

One general example of a known process for forming an integrated inductor will be described with reference to FIG. 1, which illustrates a simplified sectional view of part of semiconductor wafer at different stages of the process.

To form a set of lower winding sections for the inductor, a patterned layer 102a of a conductive material, e.g. a metallic material such as copper, is formed on a substrate 101, as illustrated in FIG. 1a. The substrate 101 will typically comprise a semiconductor wafer, such as silicon. The substrate 101 may comprise one or more layers of material formed so as to provide a suitable surface for formation of the inductor and/or which have been deposited as part of formation of other components of the integrated circuit.

The patterned conductive layer 102a may then be coated, as illustrated in FIG. 1b, with a protective/sacrificial layer 103, for instance such as a silicon dioxide or silicon nitride layer. A dielectric material 104, such as polyimide, may then be deposited over the lower winding layer 102a, as illustrated in FIG. 1c, and patterned to create openings or vias 105 to parts of the lower winding layer 102a. The dielectric 104 is deposited to a depth to provide an appropriate spacing between the lower winding layer 102a and the magnetic core of the inductor.

A magnetic layer 106, is then deposited over the planarized dielectric layer 104, as illustrated in FIG. 106. The magnetic layer may, for example, comprise cobalt-zirconium-tantalum, CoZrTa (referred to as CZT) and may be formed from a stack of thin films of deposited CZT, alternating with thin films of oxide/dielectric. The magnetic material is then etched to leave magnetic material only in areas required to form the magnetic core 107, as illustrated in FIG. 1e. The protective/sacrificial layer 103 protects the underlying conductive material 102a in the area of the exposed vias 105 during the etch of the magnetic material 106.

A further dielectric later 104b is deposited and patterned to open the vias 105 to the relevant parts of the underlying lower winding layer 102a. The sacrificial layer 103 is also removed from the areas of the vias 105, as illustrated in FIG. 1f.

A further patterned layer of conductive, e.g. metallic, material 102b is then formed on top of the dielectric to form the upper winding sections, with conductive material 102c within the vias 105 connecting the lower and upper winding sections. The lower and upper winding layers are arranged, as will be understood by one skilled in the art, so that each end of an individual lower winding section connects to different upper winding sections to form at least one continuous winding around the magnetic core. As illustrated in FIG. 1g a further dielectric layer 104c may then be formed over the inductor structure and patterned to form openings 108 for forming electrical connections to the inductor.

This process allows the formation of an integrated inductor as part of an integrated circuit.

However, the materials and process for forming the magnetic material layer need to be compatible with the fabrication of the underlying circuit, which can place limits on suitable materials and processes steps, for example on annealing and curing temperatures that can be used for forming the magnetic material.

In addition, depositing suitable materials to form the magnetic material layer can involve relatively long process times and may also involve relatively significant cost. As noted above, magnetic material layers have been formed by depositing thin films of CZT alternated with oxide. Such a deposition process can involve relatively long process times and requires the use of expensive deposition equipment and sputtering target, which can limit feasible material thickness for commercially viable products.

Also, the step of etching the magnetic material layer 106 to form the magnetic core 107 can typically result in the magnetic core having a sloped or tapered edge region.

FIG. 1e illustrates a sloped edge region 109 of the magnetic core 107, where the thickness (or height as illustrated) of the magnetic material layer varies relatively gradually over the region 109. The sloped region may have a width of several tens of microns (i.e. the slope may extend inward from the periphery of the magnetic core 107 for several tens of microns until the full height of the magnetic core is reached). In one example, where CZT was deposited to a thickness of around 6.5 μm, the sloped edge region extended inwards for about 40 μm. This results in a region around the magnetic core 107 with poorer magnetic properties. The sloped region may also limit the total thickness of the magnetic core, which may limit the resulting energy capacity of the magnetic core.

As noted above, the fabrication process also involves the use of a protective/sacrificial layer e.g. of silicon dioxide/silicon nitride, to protect the conductive material 102a of the lower winding layer during the etch of the magnetic material later 106 so as to form the magnetic core 107. This sacrificial layer must subsequently be removed from the vias 105 to allow electrical connection to the lower windings, but in general some residual sacrificial material may be left. The requirement for the sacrificial layer adds complexity to the process and can involve some processing challenges and design limitations and the residual material that remain can be a potential reliability risk.

Embodiments of the present disclosure relate to alternative methods for manufacturing integrated circuits having integral magnetic material, such as a magnetic core for a transformer or inductor or the like, and to integrated circuits produced by such methods.

In an embodiment of the present disclosure, a suitable magnetic material layer is formed separately from the formation of the integrated circuit. During fabrication of the integrated circuit, at an appropriate point in the processing for introduction of the magnetic material, one or more portions of the prefabricated magnetic material can then be positioned onto the partly formed circuit, e.g. by a pick-and-place technique or similar. The one or more portions of the prefabricated magnetic material may be placed to form the desired magnetic component, e.g. to provide a magnetic core, and then further processing, which may include deposition of subsequent layers may complete the circuit fabrication. The magnetic material is thus embedded within the IC during fabrication and thus is integral with the IC, but is not formed by deposition on the semiconductor wafer.

Forming a layer of magnetic material separately from the fabrication of the integrated circuit itself can be beneficial in that the magnetic material may be formed using process steps, e.g. annealing and/or curing temperatures, that may otherwise be inconsistent with the circuit fabrication. This can allow a greater choice of materials and/or process steps than is the case where the magnetic material is deposited and formed on the semiconductor wafer itself.

In addition, the magnetic material may be formed into a desired shape for the magnetic component prior to placement on the semiconductor wafer, e.g. by dicing of the magnetic material or the like. This means that no etch of magnetic material on the wafer may be required, which can thus eliminate the need for a proactive/sacrificial layer to protect the lower winding layers from such an etch step. Also, the shaping of the magnetic material before placement, e.g. by dicing or cutting, can avoid the sloped edge region of the magnetic material layer that results from an etching step.

Further, placement of one or more portions of the prefabricated magnetic material on the wafer can allow magnetic components to be fabricated with properties that may not be readily achievable in a deposition process, for instance shape or thicknesses, and/or, for anisotropic magnetic materials, different orientations of the magnetic axes in different locations.

FIG. 2 illustrates one example of fabrication of a magnetic material layer separate to a deposition process for forming the IC.

The magnetic layer may, as illustrated in FIG. 2a, be formed on a carrier 201, which may be any suitable substrate for forming the magnetic material layer, for example a glass or silicon substrate. In some examples, a release layer 202 may be coated onto the carrier 201, e.g. by spin coating or the like, to aid subsequent release of the magnetic material layer. The magnetic material layer 203 may then be formed on top of the release layer.

The magnetic material layer may be formed by any suitable process for forming a magnetic material. For example, the magnetic material may be formed by a deposition process, e.g. by sputtering or the like. In some instances, the magnetic material may be formed from multiple thin film layers, for example by alternating thin films of a material such as cobalt-zirconium-tantalum, CoZrTa (CZT) with films of dielectric/oxide. As noted above, however, the fact that magnetic material is formed separately on the carrier can allow the use of materials and/or process parameters such as temperature that would not be compatible with formation of the magnetic material directly on the semiconductor wafer of the IC itself.

It should be understood, however, that other techniques for forming thin films or foils may be suitable for forming magnetic material layers, for instance other deposition or plating techniques or hot or cold rolling techniques or lamination. One skilled in the art will be aware of a number of techniques for forming thin films which may be applicable for forming suitable magnetic layers for a particular application.

The magnetic material may be a material with a relative permeability of at least 2, although advantageously the relative permeability of the magnetic material may be at least 10, or in some cases could be of the order of 50 or more, or 100 or more. Note as used herein the reference to relative permeability may be taken as a reference to initial relative permeability, i.e. for low field strengths below 0.1 T as determined at standard temperature.

The magnetic material layer 203 on the carrier 201 may then be laminated to an attachment or adhesion layer 204 on a base 205, as illustrated in FIG. 2b. The attachment layer 204 may comprise adhesive material for adhering to the magnetic material layer 203, with the base 205 providing support for dicing as will be described below. The attachment layer 204 and base 205 may, in some implementations, be provide by a suitable die attach film on a dicing tape as will be understood by one skilled in the art.

The carrier 201 with release layer 202 may then be removed, e.g. following a laser debond or other release process or by grinding or the like, to leave the layer of magnetic material 203 on the attachment layer 204 and base 205. In some examples, the attachment layer then may be at least partly cured or treated, e.g. by exposure to UV radiation as illustrated in FIG. 2c, so as to reduce adhesion to the base 205 to ease subsequent removal.

The magnetic material layer 203, together with the attachment layer 204, may then be divided into a plurality of magnetic layer portions 206, where each of the magnetic layer portions may be shaped to form at least part of a magnetic component for an IC. For example, one or more portions 206 may be shaped appropriately so as to be able to form a magnetic core for an IC.

The magnetic material layer 203, may be divided into the magnetic layer portions in any suitable manner, and in at least some processes the magnetic material layer may be cut to a desired size and shape, e.g. using a suitable dicing tool 207 as illustrated in FIG. 2d. Once formed into the desired shapes, the prefabricated magnetic layer portions 206 can then be subsequently implanted within an IC as part of an IC fabrication process.

The magnetic material layer 203 formed on the attachment layer 204 and base 205 thus effectively provide a panel of magnetic material 203 from which one or more magnetic layer portions 206 can be shaped and used in IC fabrication. One panel of magnetic material may be used to provide several magnetic layer portions 206 as die components, that can be used to provide magnetic components for a plurality of different ICs. The layer of the magnetic material 203 of the panel may have any convenient size and shape for allowing the formation of suitable magnetic layer portions, and the panel could for instance be formed as a square or rectangular shape, although other shapes may be advantageous in some implementations.

FIG. 3 illustrates one example of how prefabricated magnetic layer portions may be embedded as part of an IC as part of an IC fabrication process, in this example as a magnetic core of an inductor. Similar components to those discussed with reference to FIGS. 1 and 2 will be identified by the same reference numerals.

As illustrated in FIG. 3a, a patterned layer 102a of a conductive material such as copper is formed on a substrate 101, to form a set of lower windings in a similar manner as discussed with reference to FIG. 1. As discussed above, the substrate 101 will typically comprise a semiconductor wafer, such as silicon, and may comprise one or more layers of material to provide a suitable surface for formation of the inductor and/or which have been deposited as part of formation of other components of the integrated circuit.

A dielectric material 104, such as polyimide, may then be deposited over the lower winding layer 102a, as illustrated in FIG. 3b, and exposed, developed, cured and cleaned/planarized. At least one of the prefabricated magnetic layer portions 206, comprising a portion of magnetic layer 203 with attachment layer 204, is then located on the semiconductor wafer, at an appropriate place above the lower windings to provide the magnetic core. The at least one magnetic layer portion 206 may be placed in the desired location by a pick-and-place technique, as will be understood by one skilled in the art. The attachment layer 204 may then be processed, e.g. cured, for instance by thermal curing or similar, to attach the magnetic layer portion 206 to the partly formed IC, as illustrated in FIG. 3c, although in some cases the curing could occur later or some attachment of adhesive materials could potentially be used that do not require a separate curing step.

It will be seen that the attachment or adhesion layer 204 provides at least some of the spacing between the magnetic material 203 and the lower winding layer 102a. The attachment layer 204 will generally comprise an adhesive material that, in some cases when cured, can act as a suitable spacer material for spacing the magnetic material 203 from the metallic windings 102a. In the example of FIG. 3b, dielectric material 104 is coated over the lower winding later and planarized to the level of the upper surface of the metallic layer 102a, prior to placing the magnetic layer portion 206. Thus the spacing between the lower winding layer 102a and the magnetic core in this example is defined by the cured attachment layer 204. Other approaches are possible, however. In some cases, it may be possible to omit the dielectric coating 104b over the lower winding layers, and place the magnetic layer portion 206, with attachment layer 204 on the patterned conductive layer. On placing and curing, the attachment layer 204 can flow around the patterned conductive layer and fill the areas around the lower windings as well as providing the spacing for the magnetic core material 203. In other examples, to achieve a desired spacing between the windings 102a and the magnetic core material 203, it may be preferred to have the dielectric coating 104 over the lower winding layer 102a that extends above the upper surface of the winding layer, in which case the dielectric layer may be patterned at an appropriate point to form vias for connecting the lower windings.

After the magnetic layer portion 206 has been mounted to the partly formed IC, a further dielectric layer 104b is deposited and patterned to open the vias 105 to the relevant parts of the underlying lower winding layer 102a, as illustrated in FIG. 3d.

A further patterned layer of conductive material 102b is then formed on top of the dielectric to form the upper winding sections, with conductive material 102c within the vias 105 connecting the lower and upper winding sections. The lower and upper winding layers are arranged, as described previously, to form at least one continuous winding around the magnetic core. As illustrated in FIG. 3e a further dielectric layer 104c may then be formed over the inductor structure and patterned to form openings 108 for forming electrical connections to the inductor.

This process allows the formation of an integrated inductor as part of an integrated circuit, in which prefabricated magnetic material is embedded as part of the IC during the wafer-level processing stage. This can provide an IC with the benefits of integrated magnetic material, e.g. in terms of size and/or cost, but which offers at least some improvements to the deposition process described previously.

As noted above, as the magnetic material layer is formed on a carrier which is separate to the wafer on which the IC is fabricated and is effectively prefabricated to be embedded within the IC during wafer production, the choice of materials and process steps for forming the magnetic material layer is not constrained by the need to be compatible with formation as part of the wafer/IC itself.

In addition, as the one or more portions of magnetic material used to form the magnetic core can be shaped appropriately, e.g. cut to size, before placement, there is no need for etching of the magnetic material layer on the semiconductor wafer. This means that a protective/sacrificial layer for protecting underlying metallic components, e.g. the protective layer 103 for protecting the lower winding layer 102a as discussed with reference to FIG. 1b may not be required. Omitting such a protective layer can avoid the need to remove at least part of the sacrificial layer to form electrical connections, which simplifies the processing, and also avoids any problem with residual material from such a layer impacting on reliability.

Further, shaping the magnetic layer portions by cutting, rather than etching, can avoid the issues with an undesired sloped edge region 109 as discussed with reference to FIG. 1e. Instead, an edge 301 of the magnetic material 203 of the magnetic layer portion 206 may be formed by cutting or dicing. This can provide a stepped, rather than sloped edge, as illustrated by the edge 301 of the magnetic layer portion 206 illustrated in FIG. 3c. That is, rather than a relatively gradual transition in height of an edge region over a distance of tens of microns, such as the edge region 109 of FIG. 1, the edge of the magnetic layer portion exhibits a well-defined step change in the edge. An edge region of the magnetic material 203, i.e. a region extending inwards from the outer periphery of the magnetic layer portion 206 to the full thickness of the magnetic layer 203 may extend over only a few microns and may, for example extend for less than 10 microns or less than 5 microns. A sidewall of the magnetic material 203 may thus be substantially perpendicular to the general plane of the magnetic layer portion, e.g. within 10° or within 5° of perpendicular. For example, as illustrated in FIG. 3c, the plane of the magnetic layer portion as illustrated in substantially horizontal as illustrated and the side wall of the edge 301 is substantially vertical as illustrated.

The ability to provide a magnetic material layer as part of an integrated circuit where the magnetic material layer has a stepped edge, e.g. a sidewall which is substantially perpendicular to the plane of the magnetic material layer, represents one particular aspect of this disclosure and thus aspects relate to integrated circuit including such a magnetic material layer with a stepped edge. Aspects also relate to an integrated circuit having an embedded magnetic material layer, wherein at least one edge or sidewall of the magnetic material layer is a cut edge, i.e. is an edge formed by cutting or dicing.

Shaping the magnetic material layer by cutting, rather than etching, can also allow the formation of magnetic components having shapes that may not be readily or practicably achieved through deposition and etching of magnetic material. For example, a magnetic component of an IC, such as a magnetic core of an inductor, could be formed from a plurality of magnetic layer portions 206, each magnetic layer portion being cut to a desired shape to form part of the magnetic component.

For example, FIG. 4 illustrates how a plurality of magnetic layer portions may be cut from a panel of prefabricated magnetic material and used to form a magnetic component. The left-hand side of FIG. 4 illustrates, in plan view, at least part of the panel of magnetic material 203 and illustrates four magnetic layer portions 206a-d that may be cut from such a panel, which in this example are all rectangular. The right-hand side of FIG. 5 illustrates, again in plan view, how the four magnetic layer portions 206a-d could be placed on the IC wafer, so as to form a magnetic component. In this example the four magnetic layer portions 206a-d are arranged adjacent one another to provide a toroidal-type magnetic core 401. FIG. 4 also illustrates generally that the magnetic layer portions 206a-d are arranged with respect to lower windings 402 and upper windings 403 to provide at least one set of windings around the toroidal core.

Note that as used herein, the terms toroid and toroidal shall be taken to mean a shape which is annular in plan view, i.e. describes a path which forms a closed loop and shall include circular annular shapes and non-circular annual shapes, e.g. square or rectangular annular shapes or other annular polygon shapes.

In general, toroidal shapes for an inductor or transformer can be beneficial in terms of efficiency in use. However, for inductors or transformers with a core magnetic material which exhibits magnetic anisotropy, annular or toroidal shapes may generally not be preferred. As will be understood by one skilled in the art, at least some thin film magnetic materials, such as CZT, may exhibit magnetic anisotropy and thus may exhibit an easy axis along one direction in which is the material is more susceptible to magnetization than along the hard axis in an orthogonal direction. The direction of the hard and easy axes arises from the material properties, such as crystalline structure, and thus each of the hard and easy axes is generally constant in one direction for a continuous material. Thus, a continuous layer of magnetic material may tend to have, within the plane of the layer, the easy axis in one direction and the hard axis in the orthogonal direction.

For performance reasons it can be beneficial to provide, as far as possible, a desired alignment between the magnetic field generated in use and the hard and easy axes of the magnetic core. For example, in some applications it may be desirable to align, as far as possible, the magnetic field generated with the hard axis of the magnetic core.

If, however, a continuous layer of an anisotropic magnetic material was formed into a toroidal shape, the alignment of the hard and easy axes of the magnetic core to the magnetic field direction may vary around the toroid, which can be disadvantageous. Generally, therefore, inductors and transformers formed as part of an IC with a magnetic core may be arranged with at least one set of windings around a generally linear core.

In embodiments of the present disclosure, however, the panel of magnetic material 203 may be fabricated from a magnetically anisotropic material and then divided into different magnetic layer portions which can be placed in different orientations on the IC wafer, so as to form a magnetic component in which the direction of the hard and easy axes is different in different locations.

Thus, as illustrated in FIG. 4, the panel of magnetic material 203 may be formed from a magnetically anisotropic material and may thus have a magnetic axis in a first direction 404 within the plane of the layer. The magnetic axis may, for instance, be the hard axis and thus the easy axis of the magnetic material 203 may, within the plane of the layer, be perpendicular to the first direction 404.

The magnetic layer portions 206a-d which are taken from the panel of magnetic material 203 may be shaped to have a desired alignment to the first direction 404, in this example the magnetic layer portions 206a-d extend lengthways along the first direction 404.

When formed into the toroidal core 401, the different orientations of the magnetic layer portions 206a-d mean that the orientation of the hard axis of the magnetic material varies around the structure as illustrated by the arrows. This can improve the alignment between the magnetic field and the desired magnetic axis around the toroid, which can allow the advantages of a toroidal inductor or transformer to be realised without the disadvantages of misalignment of the magnetic field to the desired magnetic axis.

It can also be seen that the use of multiple magnetic layer portions 206a-d to form the magnetic core 401 can be efficient in terms of use of the magnetic material. In this example the four magnetic layer portions can be taken from one continuous area of the panel of magnetic material 203, which avoids wastage that would be associated with depositing a continuous area and then removing material from the centre region to form a toroid. Thus, in some cases, there may be advantages in forming the magnetic core from multiple different portions even for magnetic material that is magnetically isotropic.

FIG. 4 illustrates that each of the magnetic layer portions 206 may be cut to be substantially rectangular, but other shapes are possible. For example, FIG. 5, illustrates another example where multiple magnetic layer portions 206 are formed, e.g. cut, from the panel of magnetic material and placed to form an octagonal toroidal core 501. As discussed with respect to FIG. 4, the magnetic material 203 may, in some cases be magnetically anisotropic and the magnetic layer portions 206 could be shaped to have a defined orientation with respect to a hard axis 404 of the magnetic material.

In general, therefore, the one or more magnetic layer portions 206 that are formed from the panel of magnetic material 203 and used to form a magnetic component of an IC can have a range of different shapes. An individual magnetic layer portion 206 may could be rectangular or could be formed into some polygon shape, whether regular or irregular and thus may have some side walls that are angled from one another at angles other than substantially 90°. In some cases, with the use of specialist dicing tools, a magnetic layer portion could be shaped so as to have a generally curved edge. In some cases, at least one of the magnetic layer portions 206 used to form at least part of the magnetic component of the IC, e.g. the magnetic core, may have a relatively complex shape that may not be readily achievable through deposition and etching. It will be understood that FIGS. 4 and 5 illustrate that the magnetic cores 401 and 501 may be formed by multiple magnetic layer portions 206, where all of the magnetic layer portions 206 have the same general shape as one another, but it would be possible to use magnetic layer portions 206 of different shapes to form a magnetic component.

As discussed previously, for the deposition process discussed with reference to FIG. 1, there is generally a limit on the thickness of magnetic material layer 106 that can be formed, at least partly because the extent of the sloped edge region that results from etching may be greater for greater overall thickness. This can result in the magnetic core having a width that is significantly greater than its thickness. For example, for a generally linear, rectangular magnetic core, the thickness of the magnetic core could be of the order of 6 μm or so, whereas the width may be of the order of 1 mm or so. The performance of the inductor or transformer may generally be improved if the thickness of the core could be increased, and in some cases the preferred arrangement, if possible, would be to have the thickness of the magnetic core to as close to the width of the core as possible.

As the process according to embodiments of the present invention does not involve an etch of the magnetic material layer 203, the thickness of the magnetic material layer 203 is not limited by the presence of a sloped edge region that may result from the etch. Likewise, the initial fabrication of the magnetic material layer 203 on a carrier, allowing the use materials and processes that need not be compatible with IC fabrication, may allow for the thickness of the magnetic material layer to be greater than would be the case for deposition and formation on the IC wafer. However, there may still be practical limitations on the thickness of the magnetic material 203.

In some embodiments, however, the thickness of the magnetic core may be improved by stacking a plurality of magnetic layer panels or portions 206 of magnetic material on top of one another, as illustrated in FIG. 6. FIG. 6 illustrates a cross section through part of a magnetic core 601 which is formed from a plurality of magnetic layer portions 201-1 to 206-n. FIG. 6 illustrates a cross-section widthways through a part of the magnetic core as formed, and thus could, for example be a widthways section through one of the arms of the magnetic cores 401 or 501 illustrated in FIG. 4 or 5.

FIG. 6 illustrates that a first magnetic layer portion 206-1 may be placed on top of planarized layer of dielectric 104 as discussed above with reference to FIG. 3c. The magnetic layer portion 206-1 comprises the magnetic material 203 and attachment layer 204 (not separately illustrated). Subsequently a second magnetic layer portion 206-2 is place on top of the first magnetic layer portion 206-1. The second magnetic layer portion 206-2 may have the same shape as the first magnetic layer portion 206-1 and may be placed using a pick-and-place technique. In some cases this process could be repeated a desired number of times to provide a stack of n magnetic layer portions on top of one another. In some case there may be a curing or treatment step after the placement of each magnetic layer portion, e.g. 206-1, before placement of the next, e.g. 206-2, but in some cases it may be possible to place a plurality of portions on top of one another prior to curing or for some materials there may not be a need for a separate curing step.

It will be understood that the stack will include a plurality of layers of magnetic material 203 interleaved by attachment layers 204, but the stack will function generally as a magnetic core of the thickness of the total height of the stack, illustrated as Z in FIG. 6. As mentioned above, in some cases it may be desirable for the dimension Z to be as close to the width of the core, illustrated by X, as possible. However, in some cases there may be practical limitations on the number of magnetic layer portions that can be stacked on one another. Nevertheless, embodiments of the present disclosure allow the formation of a magnetic core with thickness that may be significantly greater than could feasibly be achieved through the deposition process discussed with reference to FIG. 1, for instance the thickness of the magnetic component could be greater than 10 μm, or greater than 20 μm. In some cases the magnetic component may have a thickness up to 100 μm or more. Aspects thus relate to an IC with an integral magnetic component, such as a magnetic core, wherein the thickness of the magnetic component is greater than 10 μm, or greater than 20 μm, and to methods of manufacture. Aspects also relate to an IC with an integral magnetic component, such as a magnetic core, wherein the magnetic component is formed from a stack of embedded magnetic layer portions.

Embodiments of the present disclosure thus relate to methods of forming an integrated circuit on a semiconductor wafer that involves embedding at least one portion of a prefabricated material within the IC during wafer fabrication. In the embodiments discussed above the prefabricated material is a magnetic material which is embedded within the IC to form at least part of a magnetic component, e.g. a magnetic core for an inductor or a transformer, although other applications may use embedded magnetic material for other purposes. Note that as used herein, the term magnetic component shall refer to a component of the integrated circuit which is formed substantially from magnetic material. The magnetic component may form part of a circuit component of the integrated circuit, e.g. a magnetic core of an inductor or transformer or the like.

The principles described herein could, however, additionally or alternatively be extended to embedding of other types of prefabricated material to form other components. For instance, in some applications it may be desirable for a component to have a particular temperature coefficient of resistance (TCR). One or more portions of material can be prefabricated and shaped to have the desired TCR and then embedded as part of the IC fabrication. In some applications at least part of an integrated capacitor could be formed from one or more prefabrication portions, e.g. thin film capacitor layer could be prefabricated with desired properties and embedded within the IC, rather than being formed on the wafer by deposition. There may be a range of applications in which embedding at least one portion of a prefabricated material within the IC during fabrication, to form at least part of a component, may provide benefits compared to forming that component on the wafer itself by deposition.

It will be understood that the prefabricated layer is embedded within the integrated circuit itself, i.e. is located on the wafer during formation of the IC and then other circuit layers are subsequently formed on top. The embedded component thus (once the IC fabrication is completely and the IC is singulated) forms part of the IC die or chip. This is different to the lamination of prefabricated material to a circuit board or the like.

The IC as fabricated will then be packaged and can then subsequently be used to form part of an electronic device. In some case the IC may be packaged as a wafer-level package or as a fan-out package.

Some embodiments relate to a system or method of manufacturing an embedded inductor, comprising a magnetic layer prefabricated outside of a semiconductor deposition process in a sheet or panel of a predetermined thickness. The predetermined thickness may have a dimension, e.g. vertical, that is substantially smaller than the orthogonal dimensions, e.g. the horizontal dimension. The sheet or panel of magnetic layer may have at least one adhesive layer attached thereto and at least one supportive layer, such as a dicing tape, attached to the at least one adhesive layer. The magnetic layer and the at least one adhesive layer may be diced to form a plurality of magnetic cores of a desired size and shape, with the magnetic cores being attached to a semiconductor wafer, e.g., using a pick-and-place process.

The semiconductor wafer may include various layers deposited prior to having the magnetic cores attached and/or there may be various additional layers subsequently deposited substantially over the said magnetic cores. The additional layers may include electrically insulating and electrically conducting materials, the conducting materials forming windings of an inductor substantially enclosing at least one of said magnetic cores. The system and method may be used for both wafer-level package and fan-out package technologies. In some cases the system and method may be applied to laminate-based package substrate manufacturing.

Embodiments may thus relate to an integrated circuit and to methods of manufacture thereof. Such an integrated circuit may be implemented in a host device, especially a portable and/or battery powered host device such as a mobile computing device for example a laptop, notebook or tablet computer, or a mobile communication device such as a mobile telephone, for example a smartphone. The device could be a wearable device such as a smartwatch. The host device could be a games console, a remote-control device, a home automation controller or a domestic appliance, a toy, a machine such as a robot, an audio player, a video player. It will be understood that embodiments may be implemented as part of a system provided in a home appliance or in a vehicle or interactive display. There is further provided a host device incorporating the above-described embodiments.

It should be noted that the above-mentioned embodiments illustrate rather than limit the invention, and that those skilled in the art will be able to design many alternative embodiments without departing from the scope of the appended claims. The word “comprising” does not exclude the presence of elements or steps other than those listed in a claim, “a” or “an” does not exclude a plurality, and a single feature or other unit may fulfil the functions of several units recited in the claims. Any reference numerals or labels in the claims shall not be construed so as to limit their scope

As used herein, when two or more elements are referred to as “coupled” to one another, such term indicates that such two or more elements are in electronic communication or mechanical communication, as applicable, whether connected indirectly or directly, with or without intervening elements.

This disclosure encompasses all changes, substitutions, variations, alterations, and modifications to the example embodiments herein that a person having ordinary skill in the art would comprehend. Similarly, where appropriate, the appended claims encompass all changes, substitutions, variations, alterations, and modifications to the example embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative. Accordingly, modifications, additions, or omissions may be made to the systems, apparatuses, and methods described herein without departing from the scope of the disclosure. For example, the components of the systems and apparatuses may be integrated or separated. Moreover, the operations of the systems and apparatuses disclosed herein may be performed by more, fewer, or other components and the methods described may include more, fewer, or other steps. Additionally, steps may be performed in any suitable order. As used in this document, “each” refers to each member of a set or each member of a subset of a set.

Although exemplary embodiments are illustrated in the figures and described below, the principles of the present disclosure may be implemented using any number of techniques, whether currently known or not. The present disclosure should in no way be limited to the exemplary implementations and techniques illustrated in the drawings and described above.

Unless otherwise specifically noted, articles depicted in the drawings are not necessarily drawn to scale.

All examples and conditional language recited herein are intended for pedagogical objects to aid the reader in understanding the disclosure and the concepts contributed by the inventor to furthering the art, and are construed as being without limitation to such specifically recited examples and conditions. Although embodiments of the present disclosure have been described in detail, it should be understood that various changes, substitutions, and alterations could be made hereto without departing from the spirit and scope of the disclosure.

Although specific advantages have been enumerated above, various embodiments may include some, none, or all of the enumerated advantages. Additionally, other technical advantages may become readily apparent to one of ordinary skill in the art after review of the foregoing figures and description.

To aid the Patent Office and any readers of any patent issued on this application in interpreting the claims appended hereto, applicants wish to note that they do not intend any of the appended claims or claim elements to invoke 35 U.S.C. § 112(f) unless the words “means for” or “step for” are explicitly used in the particular claim.

1. An integrated circuit comprising:
a first set of one or more circuit layers on a semiconductor substrate;
at least one fabricated magnetic layer portion forming a magnetic component on the first set of circuit layers, wherein the at least one fabricated magnetic layer portion comprises a magnetic layer coupled to the first set of one or more circuit layers by an adhesion layer; and
a second set of one or more circuit layers on top of the first set of circuit layers and the at least fabricated magnetic layer portion.

2. The integrated circuit of claim 1 wherein the at least one fabricated magnetic layer portion has an edge formed by cutting.

3. The integrated circuit of claim 1 wherein the at least one fabricated magnetic layer portion has an edge sidewall which is substantially perpendicular to a plane of the magnetic layer portion.

4. The integrated circuit of claim 1 wherein the at least one fabricated magnetic layer portion is magnetically anisotropic with a magnetic hard axis.

5. The integrated circuit of claim 4 wherein the at least one prefabricated magnetic layer portion comprises a plurality of magnetic layer portions, wherein at least some of the plurality of magnetic layer portions are oriented so that the magnetic hard axis is oriented in different directions at different positions of the magnetic component.

6. The integrated circuit of claim 1 wherein the magnetic component comprises a plurality of fabricated magnetic layer portions stacked on top of one another.

7. The integrated circuit of claim 1 wherein the thickness of the magnetic component formed by the at least one prefabricated magnetic layer portion is at least 10 μm.

8. The integrated circuit of claim 1 wherein the at least one prefabricated magnetic layer portions form a magnetic component with a toroidal shape.

9. The integrated circuit of claim 8 wherein the magnetic component comprises a plurality of magnetic layer portions forming the toroidal shape.

10. The integrated circuit of claim 1 wherein the magnetic component is a magnetic core of an inductor or a transformer.

11. The integrated circuit of claim 10 wherein the first set of circuit layers comprises a first conductive layer patterned to form a set of lower windings for the inductor or transformer and the second set of circuit layers comprises a second conductive layer patterned to form a set of upper windings for the inductor.

12. A method of fabricating an integrated circuit comprising:
forming a first set of one or more circuit layers on a semiconductor substrate;
placing at least one prefabricated magnetic layer portion onto the first set of circuit layers to form a magnetic component; and
forming a second set of one or more circuit layers over the first set of circuit layers and the at least prefabricated magnetic layer portion.

13. The method of claim 12 wherein the least one prefabricated magnetic layer portion comprises a layer of magnetic material and an attachment layer.

14. The method of claim 12 wherein the at least one prefabricated magnetic layer portion has an edge formed by cutting.

15. The method of claim 12 wherein the at least one prefabricated magnetic layer portion has an edge sidewall which is substantially perpendicular to a plane of the magnetic layer portion.

16. The method of claim 12 wherein the at least one prefabricated magnetic layer portion is magnetically anisotropic with a magnetic hard axis and placing at least one prefabricated magnetic layer portion onto the first set of circuit layers to form a magnetic component comprises placing a plurality of magnetic layer portions onto the first set of circuit layers, wherein at least some of the plurality of magnetic layer portions are oriented so that the magnetic hard axis is oriented in different directions at different positions of the magnetic component.

17. The method of claim 12 wherein placing at least one prefabricated magnetic layer portion onto the first set of circuit layers to form a magnetic component comprises stacking a plurality of prefabricated magnetic layer portions on top of one another.

18. The method of claim 12 wherein the at least one prefabricated magnetic layer portion is cut from a panel comprising a layer of magnetic material on an attachment layer on a base.

19. The method of claim 18 wherein the base comprises a dicing tape.

20. The method of claim 18 wherein the prefabricated magnetic layer is formed on a carrier and transferred to the attachment layer on the base to form the panel.

21. An integrated circuit comprising an integrated inductor or transformer having a magnetic core wherein a sidewall of the magnetic core is substantially perpendicular to a plane of the magnetic core.
